(19) United States
(12) Patent Application Publication
(10) Pub. No.: US 2012/0074437 A1
(43) Pub. Date: Mar. 29, 2012

(54) LED UNIT HAVING UNIFORM LIGHT EMISSION

(75) Inventors: SHIUN-WEI CHAN, Hukou (TW); CHIH-HSUN KE, Hukou (TW)

(73) Assignee: ADVANCED OPTOELECTRONIC TECHNOLOGY, INC., Hsinchu Hsien (TW)

(21) Appl. No.: 13/178,521

(22) Filed: Jul. 8, 2011

(30) Foreign Application Priority Data
Sep. 28, 2010 (CN) 201010285120.2

(51) Int. Cl. H01L 33/62

(52) U.S. Cl. 257/88; 257/E33.066

(57) ABSTRACT

An LED unit includes a plurality of LEDs connected to each other and a plate supporting the LEDs. Each LED includes a base, a chip mounted on the base, a pair of leads fixed to the base and electrically connected to the chip and an encapsulant sealing the chip. The base includes a main body and a pair of steps. The leads each have two opposite ends protruding from two opposite ends of the main body and located below/above a corresponding step. The protruding ends of the leads of adjacent LEDs are connected to each other. The encapsulants of adjacent LEDs are continuously connected together. Light emitted from the chips of the LEDs are evenly distributed in the encapsulants whereby the light from the LEDs forms a rectangular, uniform light source.

### BACKGROUND

1. Technical Field

The present disclosure relates to an LED (light emitting diode) unit, and more particularly, to an LED unit having uniform light emission.

2. Description of Related Art

As new type light source, LEDs are widely used in various applications. A conventional LED includes a base, a pair of leads fixed in the base, a chip mounted on the base and electrically connected to the leads and an encapsulant secured to the base and sealing the chip. Generally, multiple LEDs are mounted to a printed circuit board for electrical connections.

However, the LEDs are generally mounted on the printed circuit board in a manner that adjacent LEDs are spaced predetermined distances from each other. The distances between the LEDs cause a result that, when viewed from a top of the printed circuit board, the LEDs seems to present multiple discontinuous shining spots. Thus, the whole light emission of the LEDs is uneven. Furthermore, such discontinuous shining spots may result in glare which is undesired in general illumination.

What is needed, therefore, is an LED unit which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a side view of an LED unit in accordance with an embodiment of the present disclosure.

FIG. 2 is an isometric view of an LED of the LED unit of FIG. 1.

FIG. 3 is an inverted view of the LED of FIG. 2.

FIG. 4 is a side view of the LED of FIG. 2.

FIG. 5 shows an exploded view of a pair of leads of the LED of FIG. 2.

FIG. 6 shows an assembled view of the pair of leads of the LED of FIG. 5.

FIG. 7 shows an assembled view of a pair of leads of an LED of an LED unit in accordance with another embodiment of the present disclosure.

### DETAILED DESCRIPTION OF THE EMBODIMENTS

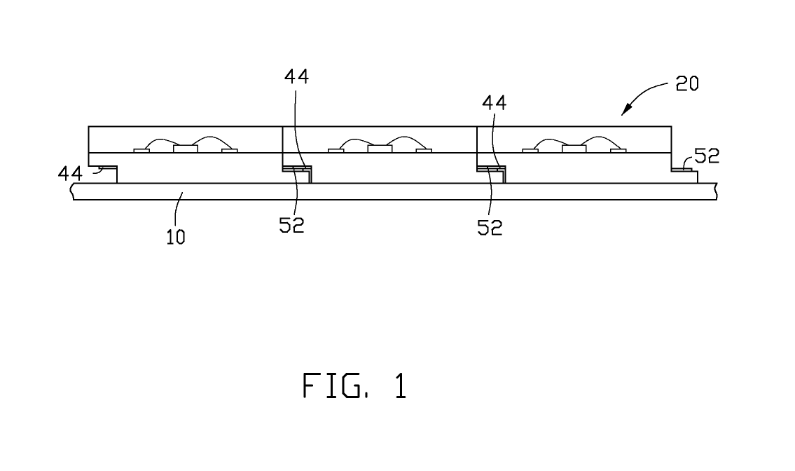

Referring to FIG. 1, an LED (light emitting diode) unit in accordance with an embodiment of the present disclosure is shown. The LED unit includes a plate 10 and a plurality of LEDs 20 mounted on the plate 10.

The plate 10 may be made of a heat conductive material, such as metal, ceramic or other suitable materials. The plate 10 has a flat top face on which the LEDs 20 are mounted.

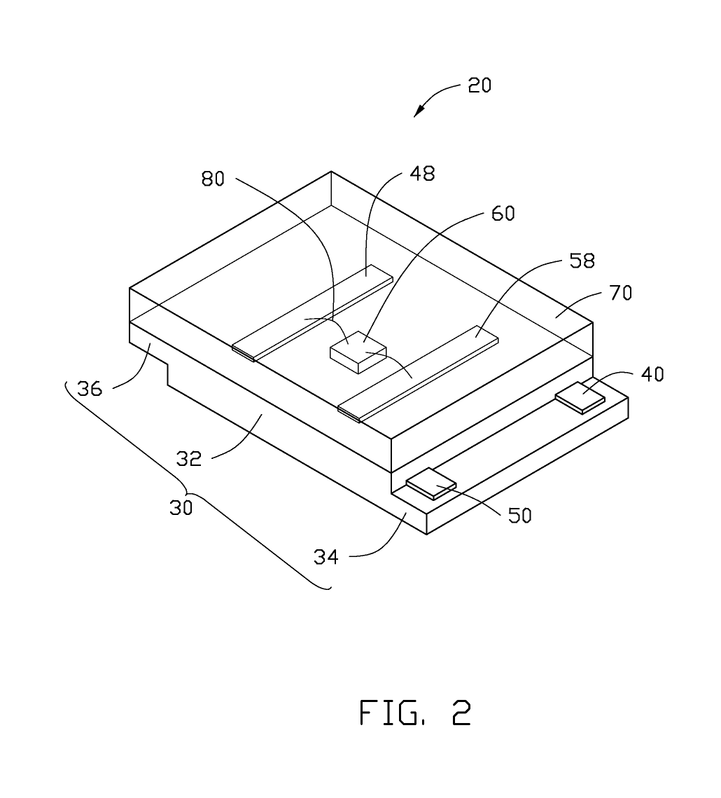

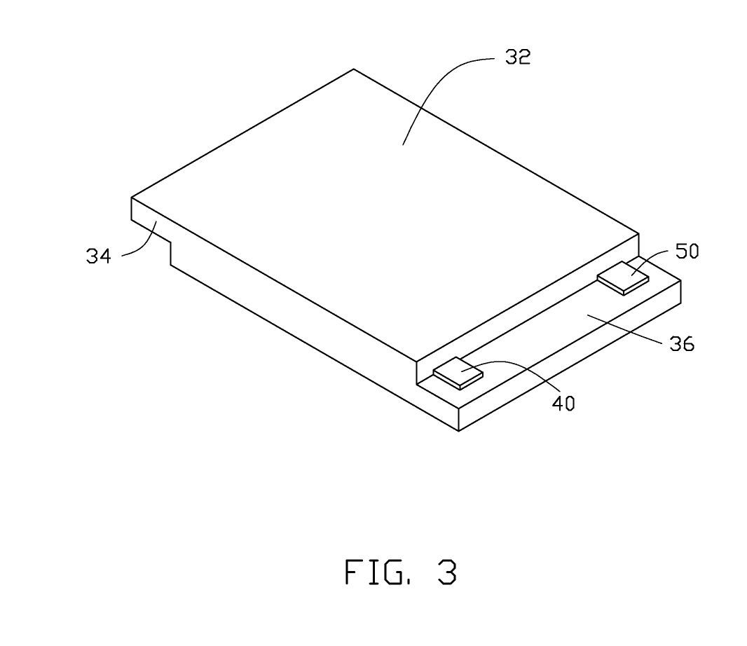

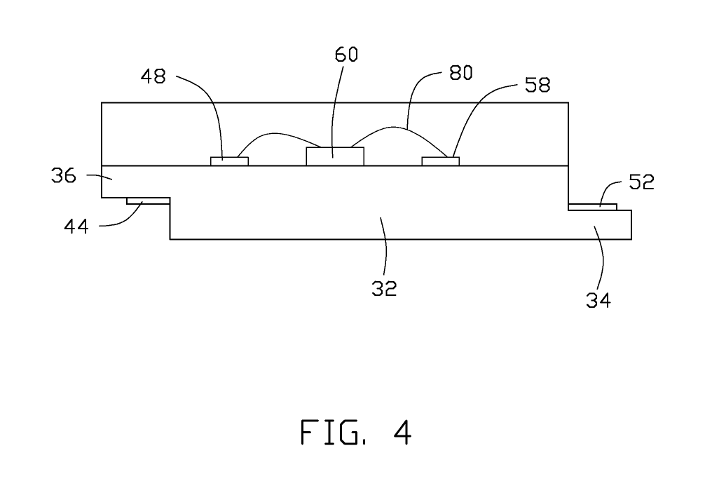

Also referring to FIGS. 2-4, each LED 20 includes a base 30, a pair of leads 40, 50 fixed to the base 30, a chip 60 mounted on the base 30 and electrically connected to the leads 40, 50 and a plate-like encapsulant 70 attached to the base 30 and sealing the chip 60. The base 30 may be made of an electrically-insulating and heat-conducting material such as ceramic. The base 30 includes a main body 32 and a first step 34 and a second step 36 protruding from two opposite ends of the main body 32, respectively. The first step 34 is extended from a lower portion of a front end of the main body 32 and faces upwardly. The second step 36 is extended from an upper portion of a rear end of the main body 32 and faces downwardly. The first step 34 and the second step 36 are complementary to each other.

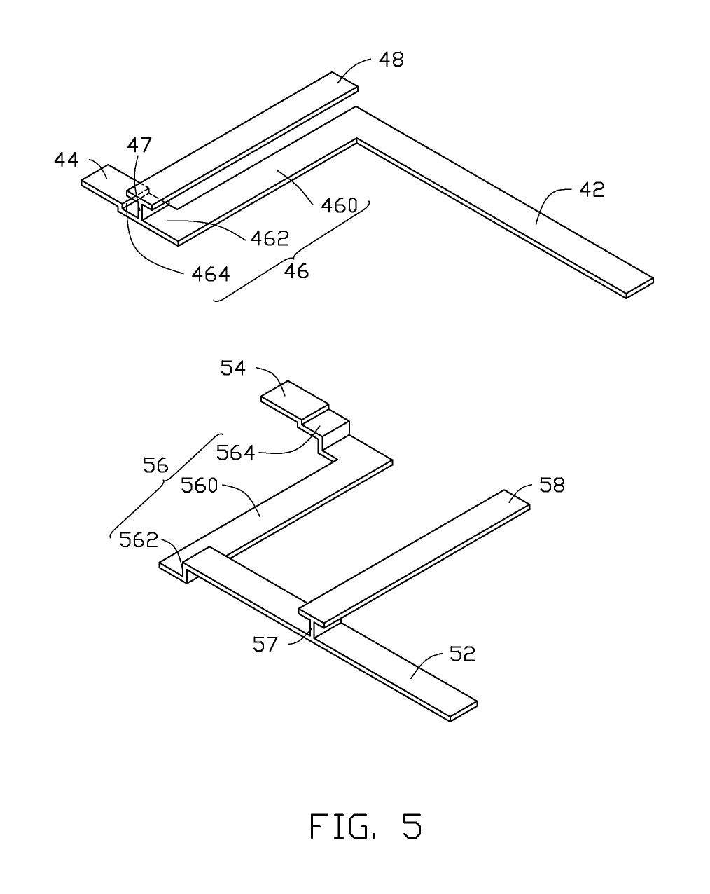

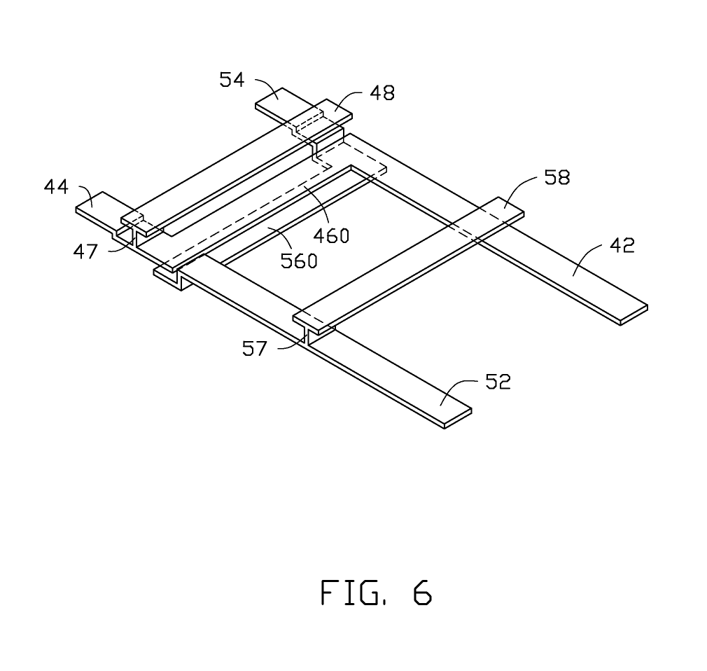

Also referring to FIGS. 5-6, the pair of leads 40, 50 each are made of an electrically conductive material such as copper, aluminum or other suitable metals. The pair of leads 40, 50 include a first lead 40 and a second lead 50 spaced from the first lead 40. Each of the first lead 40 and the second lead 50 includes a first contact section 42, 52, a second contact section 44, 54 and a connection section 46, 56 connecting the first contact section 42, 52 with the second contact section 44, 54. The first contact section 42 of the first lead 40 has a strip configuration extending along a front-to-rear direction of the base 30. The second contact section 44 of the first lead 40 is also extended along the front-to-rear direction of the base 30. The second contact section 44 of the first lead 40 has a length less than that of the first contact section 42 and a width equal to that of the first contact section 42. The second contact section 44 of the first lead 40 is located higher than the first contact section 42. The connection section 46 of the first lead 40 includes a beam 460 extending perpendicularly from a rear end of the first contact section 42, a wall 464 extending downwardly from a front end of the second contact section 44 and a piece 462 interconnecting the beam 460 and the wall 464. The beam 460 and the piece 462 are coplanar with the first contact section 42. The piece 462 is perpendicular to the beam 460 and parallel to the first contact section 42. The piece 462 has a length less than that of the beam 460 and the first contact section 42. The wall 464 is perpendicular to the second contact section 44 and the piece 462. The wall 464 has a small height so that the second contact section 44 is raised a little higher than the first contact section 42.

The first contact section 52 and the second contact section 54 of the second lead 50 have the same shapes as those of the first contact section 42 and the second contact section 44 of the first lead 40, respectively. The first contact section 52 of the second lead 50 is parallel to and coplanar with the first contact section 42 of the first lead 40, and the second contact section 54 of the second lead 50 is parallel to and coplanar with the second contact section 44 of the first lead 40. A rear end of the first contact section 52 of the second lead 50 is spaced a small gap from a front side of the beam 460 of the first lead 40, preventing a direct contact between the first lead 40 and the second lead 50. The connection section 56 of the second lead 50 is located below and spaced a distance from the connection section 46 of the first lead 40. The connection section 56 of the second lead 50 includes a piece 562 extending downwardly from a rear end of the first contact section 52, an inverted L-shaped wall 564 extending downwardly from a front end of the second contact section 54 and a beam 560 interconnecting the piece 562 and the wall 564. The piece 562 is oriented vertically and has a height larger than that of the wall 464 of the first lead 40. The beam 560 is located lower than the first contact section 52. The beam 560 of the second lead 50 is parallel to and located just below the beam 460 of the first lead 40. The wall 564 of the second lead 50 is bent plural times from the second contact section 54 to the beam 560. The wall 564 of the second lead 50 is also spaced a small distance from a rear side of the beam 460 of the first lead 40, preventing a direct contact between the first lead 40 and the second lead 50.

The first lead 40 and the second lead 50 each include a horizontal bridge 48, 58 and a vertical tab 47, 57 perpendicular to the bridge 48, 58. The tab 47 of the first lead 40 is erected from the piece 462 to support the bridge 48 above the connection section 46 of the first lead 40. The tab 57 of the second lead 50 is erected from a middle of the first contact section 52 to support the bridge 58 above the first contact section 52 of the second lead 50. The tabs 47, 57 of the first lead 40 and the second lead 50 have the same height which is larger than that of the wall 44 of the first lead 40 so that the bridges 48, 58 are supported in a same plane higher than that of the second contact sections 44, 54 of the first lead 40 and the second lead 50. The bridge 48 of the first lead 40 is extended from the piece 462 of the connection section 46 towards the wall 564 of the second lead 50, and the bridge 58 of the second lead 50 is extended from the first contact section 52 towards the first contact section 42 of the first lead 40. The bridges 48, 58 of the first lead 40 and the second lead 50 have the same length as that of the beams 460, 560. The bridges 48, 58 of the first lead 40 and the second lead 50 are parallel to the beams 460, 560 and perpendicular to the first contact sections 42, 52.

The first lead 40 and the second lead 50 are both embedded within the base 30. The first contact section 42 of the first lead 40 and the second contact section 54 of the second lead 50 are both located at the right side of the base 30, and the first contact section 52 of the second lead 50 and the second contact section 44 of the first lead 40 are both located at the left side of the base 30. Front ends of the first contact sections 42, 52 of the first lead 40 and the second lead 50 protrude out of the main body 32 and are exposed on a top face of the first step 34, while rear ends of the second contact sections 44, 54 of the first lead 40 and the second lead 50 protrude out of the main body 32 and are exposed on a bottom face of the second step 36. The tabs 47, 57 of the first lead 40 and the second lead 50 are substantially embedded within the main body 32 and support the bridges 48, 58 which are exposed on a top face of the main body 32.

The chip 60 is fixed on the top face of the main body 32 by a heat conductive adhesive such as silver paste. The chip 60 may be made of GaN, InGaN, InAlGaN, GaAs or other suitable light emitting semiconductor materials, depending on the actual requirements regarding the light color. The chip 60 is electrically connected to the two bridges 48, 58 through two wires 80.

The encapsulant 70 is molded on the top face of the base 30 to seal the chip 60 and the wires 80 therein. The encapsulant 70 may be made of epoxy, silicon, glass or other transparent materials. The encapsulant 70 has an area coincidental with that of a top of the base 30, i.e., a combination of the top face of the main body 32 and a top face of the second step 36.

The LEDs 20 are directly connected to each other in a series manner that the exposed front end of the first contact section 42 of the first lead 40 of each LED 20 connects the exposed rear end of the second contact section 54 of the second lead 50 of an adjacent LED 20, and the exposed front end of the first contact section 52 of the second lead 50 of each LED 20 connects the exposed rear end of the second contact section 44 of the first lead 40 of the adjacent LED 20. When the LEDs 20 are required to emit light, the exposed front end of the first contact section 42 of the first lead 40 of the first one of the LEDs 20 is electrically connected to a positive electrode of a power source, and the exposed rear end of the second contact section 54 of the second lead 50 of the last one of the LEDs 20 is electrically connected to a negative electrode of the power source, thereby introducing a current from the power source to flow through the LEDs 20 so that the LEDs 20 are activated to lighten.

After the LEDs 20 are assembled and electrically connected with each other, the adjacent LEDs 20 are in direct contact with each other along a line. A rear end of the second step 36 of each LED 20 contacts an upper portion of the front end of the main body 32 of an adjacent LED 20, and a front end of the encapsulant 70 of each LED 20 contacts a rear end of the encapsulant 70 of the adjacent LED 20. Therefore, the LEDs 20 are intimately connected to each other without significant gaps between neighboring LEDs 20. The light emitted from each of the chips 60 of the LEDs 20 is evenly distributed in a corresponding encapsulant 70 and the encapsulants 70 are continuously connected together, whereby the light emitted from the connected LEDs 20 forms a rectangular, uniform light source when viewed from a top of the LEDs 20. Accordingly, glare of the light is thus prevented.

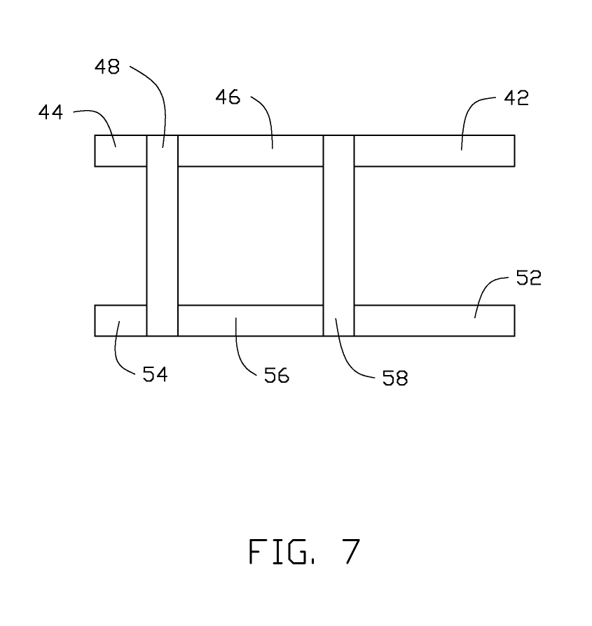

Such series connection relations between the LEDs 20 can be varied to parallel connection relations by changing the structures of the first lead 40 and the second lead 50. As shown in FIG. 7, the first lead 40 and the second lead 50 of an LED 20 of this embodiment have different configurations from those of the first lead 40 and the second lead 50 of the previous embodiment, respectively, while the other elements of the LED 20 not shown in FIG. 7 are the same as that of the previous embodiment. The first lead 40 and the second lead 50 of this embodiment have similar configurations. The first lead 40 and the second lead 50 of this embodiment each include a first contact section 42, 52, a second contact section 44, 54 and a connection section 46, 56 interconnecting the first contact section 42, 52 and the second contact section 44, 54. The first contact section 42, the second contact section 44 and the connection section 46 of the first lead 40 are all located at the right side of the base 30, and the first contact section 52, the second contact section 54 and the connection section 56 of the second lead 50 are all located at the left side of the base 30. The first contact section 42 of the first lead 40 is parallel to the second contact section 44 thereof, and the first contact section 52 of the second lead 50 is parallel to the second contact section 54 thereof. The first contact section 42 of the first lead 40 is also parallel to the first contact section 52 of the second lead 50. The connection sections 46, 56 of the first lead 40 and the second lead 50 are parallel to each other. The first contact section 42 of the first lead 40 is coplanar with the first contact section 52 of the second lead 50, and the second contact section 44 of the first lead 40 is coplanar with the second contact section 54 of the second lead 50 and located higher than the first contact sections 42, 52 of the first 40 lead and the second lead 50. Each of the first lead 40 and the second lead 50 includes a bridge 48, 58 located higher than the second contact section 44, 54 thereof, wherein the bridge 48 of the first lead 40 is connected to the connection section 46 thereof through a vertical tab (not shown in FIG. 7), and the bridge 58 of the second lead 50 is connected to the first contact section 52 through another vertical tab (not shown in FIG. 7). The bridges 48, 58 of the first lead 40 and the second lead 50 are also coplanar with each other. The physical connection relations of the first lead 40 and the second lead 50 with the other elements of the LED 20 of this embodiment are similar to those of the previous embodiment; for example, the first contact sections 42, 52 and the second contact sections 44, 54 protrude out of the main body 32, and the bridges 48, 58 are exposed on the top face of the base 30 and connected to the chip 60 through the two wires 80. The electrical connection relation of LEDs 20 with the power source of this embodiment is different from that of the pervious embodiment. In one exemplary situation, the first contact section 42 of the first lead 40 of the first one of the LEDs 20 is electrically connected to the positive electrode of the power source, and the first contact section 52 of the second lead 50 of the first one of the LEDs 20 is electrically connected to the negative electrode of the power source, to thereby energize the LEDs 20 in a parallel manner.

The LEDs 20 are self-connected with each other without using a printed circuit board, whereby the cost of the printed circuit board can be saved. Furthermore, the number of the LEDs 20 to be connected together can be arbitrarily decided, whereby the design of an LED lamp using the LED 20 can be more flexible. Furthermore, the LEDs 20 directly attached on the top face of the plate 10 can increase heat dissipation capability thereof, thereby facilitating normal operation of the LEDs 20.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. An LED (light emitting diode) unit comprising:
a plurality of individual LEDs, each of the LEDs comprising:
a base;
a light emitting chip mounted on the base; and
an encapsulant attached to the base to cover the light emitting chip;
wherein the encapsulants of adjacent LEDs are in contact with each other without gaps between the encapsulants.

2. The LED unit of claim 1, wherein the encapsulant has a circumferential periphery coincidental with that of a top of the base.

3. The LED unit of claim 2, wherein the base comprises a main body and a first step and a second step protruding oppositely from two opposite ends of the main body.

4. The LED unit of claim 3, wherein the first step protrudes from a lower portion of one of the two opposite ends of the main body, and the second step protrudes from an upper portion of the other one of the two opposite ends of the main body.

5. The LED unit of claim 4, wherein the encapsulant has a bottom face identical to a combination of a top face of the main body and a top face of the second step.

6. The LED unit of claim 4, wherein a free end of the second step of each LED contacts an upper portion of the one of the two opposite ends of the main body of an adjacent LED.

7. The LED unit of claim 4, wherein each LED further comprises a first lead and a second lead fixed to the base and electrically connected to the light emitting chip thereof, the first lead and the second lead each have two opposite ends protruding from the two opposite ends of the main body.

8. The LED unit of claim 7, wherein the ends of the first lead and the second lead protruding from the one of the two opposite ends of the main body are located on a top of the first step, and the ends of the first end and the second lead protruding from the other one of the two opposite ends of the main body are located at a bottom of the second step.

9. The LED unit of claim 7, wherein the ends of the first lead and the second lead protruding from the one of the two opposite ends of the main body of each LED are connected to the ends of the first lead and the second lead protruding from the other one of the two opposite ends of the main body of an adjacent LED.

10. The LED unit of claim 7, wherein each of the first lead and the second lead comprises a first contact section, a second contact section and a connection section interconnecting the first contact section and the second contact section, the first contact sections and the second contact sections of the first lead and the second lead protruding from the two opposite ends of the main body.

11. The LED unit of claim 10, wherein the first contact sections of the first lead and the second lead are parallel to and coplanar with each other, and the second contact sections of the first lead and the second lead are parallel to and coplanar with each other.

12. The LED unit of claim 11, wherein the second contact sections are located higher than the first contact sections.

13. The LED unit of claim 12, wherein each of the first lead and the second lead further comprises a bridge located higher than the second contact section thereof, the bridges of the first lead and the second lead being exposed on a top of the base to electrically connect with the light emitting chip.

14. The LED unit of claim 13, wherein each of the first lead and the second lead further comprises a tab, the tab of the first lead connecting the bridge with the connection section thereof, and the tab of the second lead connecting the bridge with the first contact section thereof.

15. The LED unit of claim 14, wherein the tab of each of the first lead and the second lead is perpendicular to the first contact section and the bridge thereof.

16. The LED unit of claim 10, wherein the first contact section of the first lead and the second contact section of the second lead are located at a side of the base which is opposite to another side of the base in which the second contact section of the first lead and the first contact section of the second lead are located.

17. The LED unit of claim 10, wherein the first contact section and the second contact section of the first lead are located at a side of the base, and the first contact section and the second contact section of the second lead are located at an opposite side of the base.

18. The LED unit of claim 1, wherein the encapsulant has a plate-shaped configuration.
